(19) United States
(12) Patent Application Publication
(10) Pub. No.: US 2007/0259505 A1
(43) Pub. Date: Nov. 8, 2007

(54) NON-VOLATILE MEMORY DEVICES AND METHODS FOR FORMING THE SAME

(75) Inventors: Young-Woo Park, Seoul (KR); Jung-Dal Choi, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/613,329

(22) Filed: Dec. 20, 2006

(30) Foreign Application Priority Data
May 2, 2006 (KR) 2006-39651

(51) Int. Cl. H01L 21/02

(52) U.S. Cl. 438/381

(57) ABSTRACT

Non-volatile memory devices and methods for forming the same are provided. A device isolation layer may be formed on the semiconductor substrate to define an active region. A tunneling insulation pattern, a charge storage pattern, and a blocking insulation pattern may be disposed on the active region. A gate electrode may be disposed on the blocking insulation pattern. The charge storage pattern may be arranged in a matrix and a lower surface thereof is higher than an upper surface of the device isolation layer.

### CROSS-REFERENCE TO RELATED APPLICATIONS

This U.S. non-provisional patent application claims priority under 35 U.S.C § 119 of Korean Patent Application 2006-39651 filed on May 2, 2006, the entire contents of which are hereby incorporated by reference.

### BACKGROUND OF THE INVENTION

The present invention relates to semiconductor devices and, more particularly, a to memory devices and methods for forming the same.

Generally, semiconductor memory devices can be classified into volatile memory devices such that stored data can be erased if the power supply is stopped and nonvolatile memory devices such that stored data can be maintained even if the power supply is stopped.

Nonvolatile memory devices can be categorized as floating gate type devices and charge trap type devices according to the type of data storage layer that is included in a unit cell. Floating gate memory devices may suffer integration limitations due to errors generated by a coupling effect of floating gates. Further, floating gate type devices may consume significant power relative to other device types. Accordingly, charge trap type memory devices, such as a SONOS memory device, have been considered.

Referring to FIG. 1A and FIG. 1B, which are cross sectional views of a semiconductor substrate illustrating a conventional SONOS memory device, a conventional SONOS memory device may include lower oxide 21-nitride 22-upper oxide 23 (ONO layer 25) formed on a silicon semiconductor substrate 10. A silicon gate electrode 30 may be disposed on the ONO layer 25. Source/drain regions 40 can be located in active regions 16 at opposite sides adjacent a gate electrode 30. The ONO layer 25 may be located both on the active regions 16 and the device isolation region 13. Thus, the ONO layer 25 may be located on both types of regions (the active regions and the device isolation region) below the gate electrode 30.

Based on increasing integration demands of memory devices, active regions 16 and device isolation regions 13 have generally decreased in size. Accordingly, cell-to-cell spacing between adjacent cells has also decreased. A SONOS memory device can operate by trapping electrons in ONO layer 25, especially nitride layer 22, or by emitting trapped electrons. Accordingly, a data loss may occur in a structure where the ONO layer 25 exists on the device isolation region 13 (namely, connected with ONO layer between neighboring cells). If the interval between neighboring cells is small due to a small size of the device isolation region, trapped electrons in the ONO layer may migrate to a neighboring cell thus potentially affecting an operation of the cell. Accordingly, an operating characteristic of the memory device may be degraded.

### SUMMARY OF THE INVENTION

Embodiments of the present invention are directed to non-volatile memory devices and methods for forming the same. In some embodiments, a method for forming a non-volatile memory device may include forming a preliminary device isolation layer configured to define an active region on a semiconductor substrate and configured to define a gap region on the active region to have a higher upper surface than the active region and forming a tunneling insulation layer on the active region. Methods may also include forming a charge storage layer covering the tunneling insulation layer, a side of the gap region, and a upper surface of the preliminary device isolation layer and selectively removing a charge storage layer covering the sides of the gap region and the upper surface of the preliminary device isolation layer. Such methods may also include forming a preliminary charge storage pattern configured to extend toward the active region, recessing the preliminary device isolation layer and forming a device isolation layer having a upper surface under the preliminary charge storage pattern. Methods may also include forming a blocking insulation layer and a gate conductive layer on the substrate and patterning the gate conductive layer, the blocking insulation layer, the preliminary charge storage pattern, and the tunneling insulation layer to form a gate electrode, a blocking insulation pattern, a charge storage pattern, and a tunneling insulation pattern.

In some embodiments, a non-volatile memory device may include a device isolation layer disposed in the semiconductor substrate to define an active region, a tunneling insulation pattern, a charge storage pattern, and a blocking insulation pattern disposed in the active region. Embodiments may also include a gate electrode disposed on the blocking insulation pattern, wherein the charge storage pattern may be cut on the device isolation layer and a lower surface thereof is higher than an upper surface of the device isolation layer.

### BRIEF DESCRIPTION OF THE DRAWINGS

FIG. 1A and FIG. 1B are cross-sectional views of a semiconductor substrate illustrating a conventional SONOS memory device.

FIG. 2 is a perspective view illustrating a non-volatile memory device according to some embodiments of the present invention.

FIGS. 3 to 10 are cross sectional views taken along an I-I′ axis of FIG. 2 to explain methods for forming a non-volatile memory device according to some embodiments of the present invention.

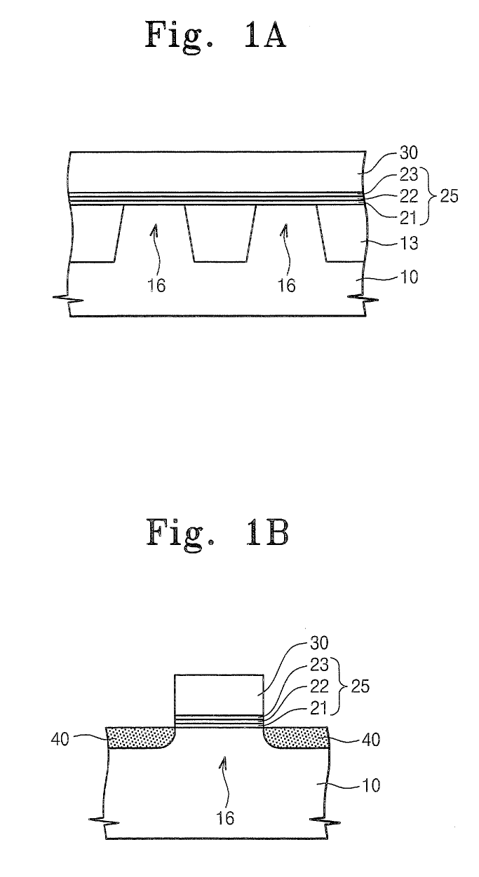

### DETAILED DESCRIPTION OF PREFERRED EMBODIMENTS

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present invention. In addition, as used herein, the singular forms “a”, “an” and “the” are intended to include the plural forms as well, unless the context clearly indicates otherwise. It also will be understood that, as used herein, the term “comprising” or “comprises” is open-ended, and includes one or more stated elements, steps and/or functions without precluding one or more unstated elements, steps and/or functions. The term “and/or” includes any and all combinations of one or more of the associated listed items.

It will also be understood that when an element is referred to as being “connected” to another element, it can be directly connected to the other element or intervening elements may be present. In contrast, when an element is referred to as being “directly connected” to another element, there are no intervening elements present. It will also be understood that the sizes and relative orientations of the illustrated elements are not shown to scale, and in some instances they have been exaggerated for purposes of explanation. Like numbers refer to like elements throughout.

In the figures, the dimensions of structural components, including layers and regions among others, are not to scale and may be exaggerated to provide clarity of the concepts herein. It will also be understood that when a layer (or layer) is referred to as being ‘on’ another layer or substrate, it can be directly on the other layer or substrate, or can be separated by intervening layers. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

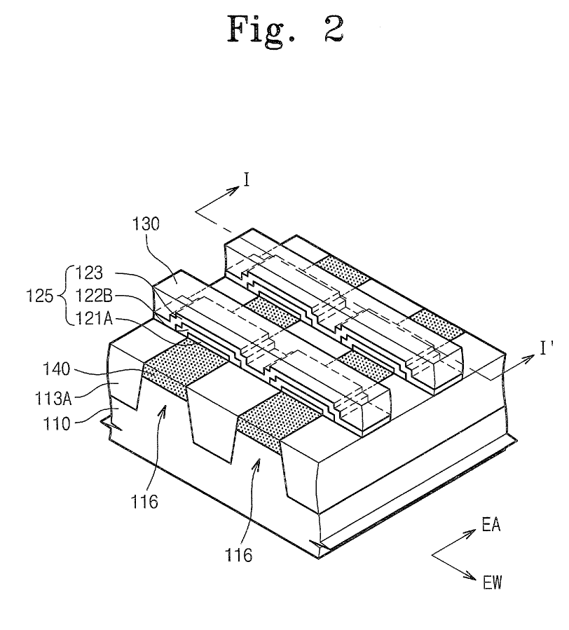

Referring to FIG. 2, which is a perspective view illustrating a non-volatile memory device according to some embodiments of the present invention, a device isolation layer 113A may be formed in a semiconductor substrate 110 to define an active region 116. An upper surface of the device isolation layer 113A may be lower than an upper surface of the active region 116 or the same. A data storage layer 125 may be located on the active region 116. The data storage layer 125 may include a tunneling insulation pattern 121A, a charge storage pattern 122B, and a blocking insulating pattern 123.

The charge storage patterns 122B may be arranged in a first direction EA and a second direction EW. The charge storage pattern 122B may be spatially and electrically isolated from a neighboring charge storage pattern and arranged in a matrix. This arrangement may prevent trapped charges in the charge storage pattern 122B from migrating to a neighboring charge storage pattern to enhance operating characteristics of the memory device.

The charge storage pattern 122B may cover an upper surface and both sides of the tunneling insulation pattern 121A. A lower surface of the charge storage pattern 122B may be located higher than an upper surface of the device isolation layer 113A. In other words, the upper surface of the device isolation layer 113 may be located under the charge storage pattern 122B to interpose a blocking insulating pattern 123 and a gate electrode 130 between the charge storage patterns 122B. Accordingly, a parasitic capacitance generated by interposing the device isolation layer between two charge storage patterns 122B may be controlled. In this manner, the charge storage pattern 122B may avoid electrical interference from a neighboring charge storage pattern to enhance an operating characteristic of the memory device.

A gate electrode 130 may be located on a data storage layer 125. The gate electrode 130 may extend in the second direction EW perpendicular to the active region 116 to constitute word lines. A source/drain region 140 may be located in active regions at opposite sides adjacent to the gate electrode 130.

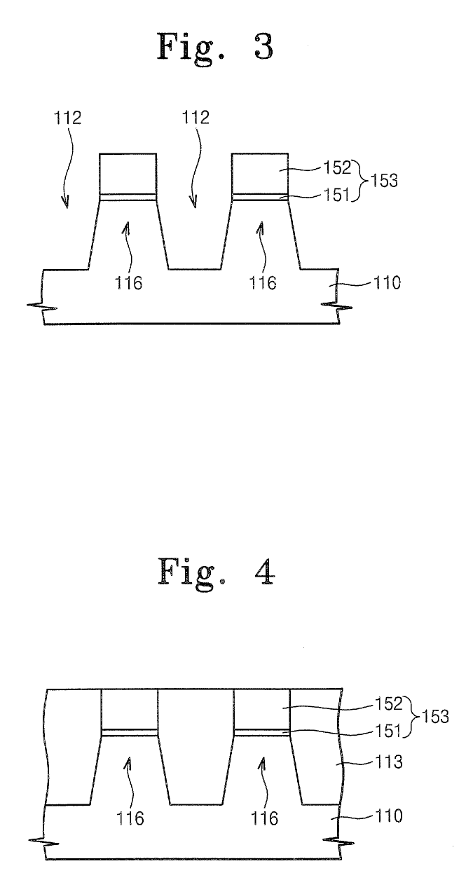

Reference is now made to FIGS. 3 to 10, which are cross sectional views taken along an I-I′ axis of FIG. 2 and presented to explain a method for forming a non-volatile memory device according to embodiments of the present invention.

Referring to FIG. 3, a mask pattern 153 may be formed on a semiconductor substrate 110. A semiconductor substrate 110 may be used as a single crystal silicon substrate or a SOI substrate. A mask pattern 153 may include an oxide layer pattern 151 and a nitride layer pattern 152. The oxide layer pattern 151 may be a pad oxide layer and may function to alleviate stress generated between the semiconductor substrate 110 and the nitride layer pattern 152. The nitride layer pattern 152 may be used as an etching mask in a follow-up process.

Using a mask pattern 153 as an etching mask, an etching process may be performed to form a trench 112. The trench 112 may define an active region 116. The semiconductor substrate 110 between the trenches 112 (below the mask pattern) may become the active region 116.

Referring to FIG. 4, after a film forming process is performed to fill the trench 112 with an insulating layer, a planarization process exposing the mask pattern 153 may be performed to form a preliminary device isolation layer 113. Before the film forming process is performed, a thermal oxidation process may be performed to cure etching damage. Further, a liner forming process may be performed to reduce the impurities from penetrating to an active region.

A high density plasma chemical vapor deposition process may be used in the film forming process. In some embodiments, the preliminary device isolation layer 113 and the mask pattern 153 may be formed as materials having an etching selectivity. In this context, an etching selectivity can mean that any material layer of two material layers may be selectively etched if proper etching gas or etching solution is used. For example, the preliminary device isolation layer 113 may be formed of a silicon oxide layer.

In the planarization process, a chemical mechanical polishing (CMP) process or an etch back process may be used. In the case of the mask pattern 153, abrasive or etching gas may be used for selectively etching the insulating layer. As a result of the planarization process, the mask pattern 153 and the preliminary device isolation layer 113 may have an upper surface of about the same height.

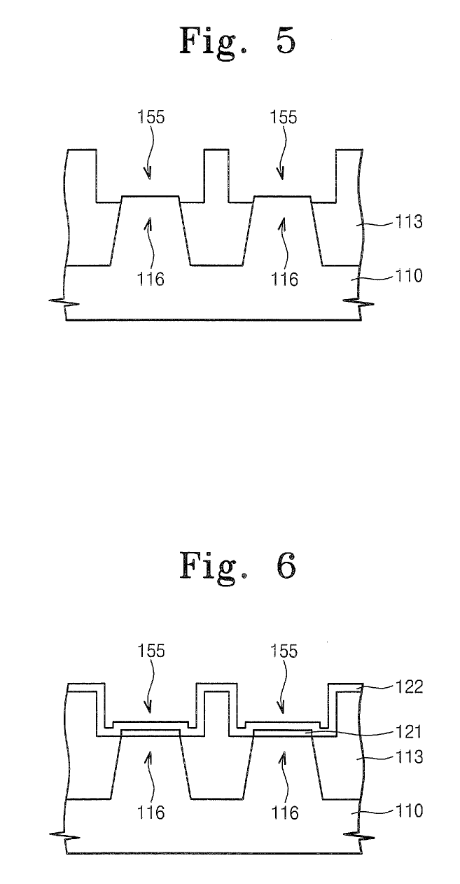

Referring to FIG. 5, an etching process may be performed to etch the mask pattern 153 and to form a gap region. The etching process can be performed as a first step of etching a nitride layer pattern 152 and a second step of etching an oxide layer pattern 151. In the first step, corresponding to the preliminary device isolation layer 113, etching gas or etching solution, such as phosphoric acid solution, may be used selectively to etch the nitride pattern 152. In the second step of etching the oxide layer pattern 151, an upper side of the preliminary device isolation layer 113 may be partially etched. Accordingly, a width of the gap region 155 may be larger than a width of removed mask pattern 153. Also, an upper surface of the active region may be projected to the gap region 155.

Referring to FIG. 6, a film forming process may be performed to form a tunneling insulation layer 121 on the active region 116. The film forming process may be a thermal oxidation process. The tunneling insulation layer 121 may be formed as a thermal oxidation layer and/or using high dielectric materials, such as hafnium oxide layer, aluminum oxide layer, hafnium aluminum oxide layer, or zirconium oxide layer.

Also, referring to FIG. 6, the film forming process may be performed to form a charge storage layer 122 covering the tunneling insulation layer 121, the sides of the gap region 155, and the upper surface of the preliminary device isolation layer 113. The charge storage layer 122 may be formed conformal to the upper surface of the semiconductor substrate formed the gap region 155 and the tunneling insulation layer 121. Conformal forming provides that a width of a material layer may be equally formed to a profile of a structure formed on the semiconductor substrate. The charge storage layer 122 may be called a charge trapping layer.

In the film forming process, a chemical vapor deposition process or an atomic layer deposition process may be used. The charge storage layer 122 may be formed of silicon nitride layer SiₓN_{y}. In some embodiments, a ratio of silicon and nitride (i.e. a ratio of x and y) may be varied. In some embodiments, the charge storage layer 122 may be formed of a material with an etching selectivity for the preliminary device isolation layer 113.

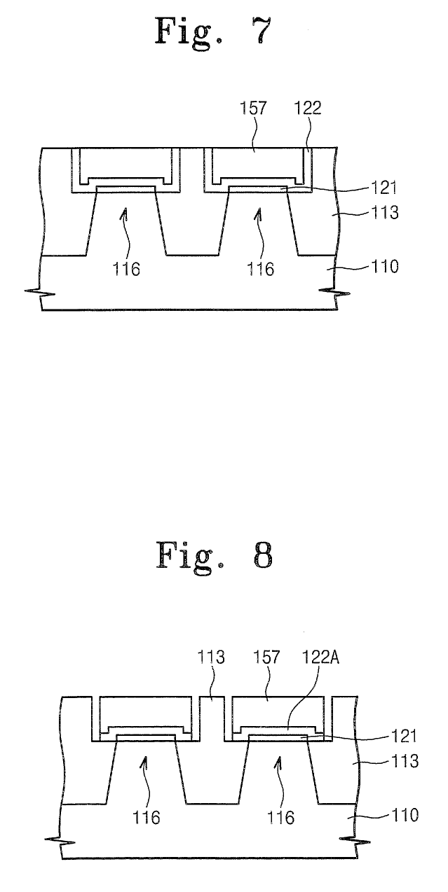

Referring to FIG. 7, after the film forming process is performed to fill the gap region 155 with an insulating layer, a planarization process may be performed to expose the charge storage layer 122 and/or the preliminary device isolation layer 113 and to form a gap insulation layer 157. In the film forming process, a chemical vapor deposition process may be used. The gap insulation layer 157 may be formed of a material with an etching selectivity for the charge storage layer 122. For example, the gap insulation layer 157 may be formed of various oxide layers such as high density plasma HDP oxide layer and of the same material as the preliminary device isolation layer 113.

Referring to FIG. 8, an etching process may be performed to etch the charge storage layer exposed between the gap insulation layer 157 and the preliminary device isolation layer 113 and to form a preliminary charge storage pattern 122A. The preliminary charge storage pattern 122A may be self-aligned under the gap insulation layer 155 to extend to a direction of the active region 116. In other words, both sides of the preliminary charge storage pattern 122A may be self-aligned at both sides of the gap insulation layer 157. The preliminary charge storage pattern 122A may cover the upper surface and sides of the tunneling insulation layer 121 covering the active region 116.

In the etching process, etching gas or etch solution, such as phosphoric acid, may be used to selectively etch the charge storage layer and to etch the gap insulation layer 157 and the preliminary device isolation layer 113.

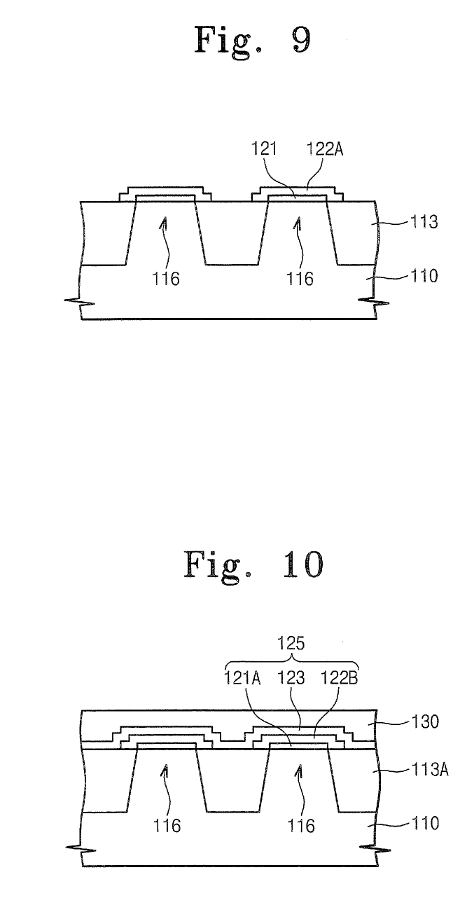

Referring to FIG. 9, an etching process may be performed to remove the gap insulation layer 157 and to expose the preliminary charge storage pattern 122A. Also, the upper part of the preliminary device isolation layer 113 may be etched to form a device isolation layer 113A. In other words, the preliminary device isolation layer 113 may be recessed to become the device isolation layer 113A such that an upper surface of the preliminary device isolation layer 113 may be located under the preliminary charge storage pattern 122A. Accordingly, a parasitic capacitance generated between neighboring charge storage patterns may be controlled and the charge storage pattern (the cell transistor) may avoid interference from the neighboring charge storage pattern (the cell transistor).

In the etching process, etching gas or etching solution, such as hydrofluoric acid, may be used for selectively etching the gap insulation layer 157 and the preliminary device isolation layer 113 and may be used for etching the preliminary charge storage pattern 122A. And, in the etching process, the gap insulation layer 157 and the preliminary device isolation layer 113 may be etched at the same time.

Referring to FIG. 10, after a film forming process is performed to form a blocking insulation layer and a gate conductive layer on the substrate, an etching process may be performed to pattern a gate conductive layer, a blocking insulation layer, a preliminary charge storage pattern, and the tunneling insulation layer and to form a gate electrode 130, a blocking insulation pattern 123, a charge storage pattern 122B, and a tunneling insulation pattern 121A. Accordingly, a data storage layer 125 including the tunneling insulation pattern 121A, the charge storage pattern 122B, and the blocking insulation pattern 123 may be formed on the active region 116.

In the film forming process, a chemical vapor deposition process may be used. The blocking insulation layer may be formed of a silicon oxide layer and/or high dielectric materials, such as hafnium oxide layer, aluminum oxide layer, hafnium aluminum oxide layer, or zirconium oxide layer. The gate conductive layer may be formed of poly silicon and/or a metal-containing layer including tantalum nitride TaN, tungsten nitride WN, or tungsten W.

In the etching process, an anisotropic etching process may be used. In this manner, the charge storage pattern 122B of a cell transistor adjacent the active region may be spatially and electrically isolated. Accordingly, trapped charges in the charge storage pattern may be prevented from moving to the charge storage pattern of the neighboring cell transistor, which may improve a property of the operation of a non-volatile memory device in highly integrated applications.

Although the present invention has been described in terms of specific embodiments, the present invention is not intended to be limited by the embodiments described herein. Thus, the scope may be determined by the following claims.

What is claimed is:

1. A method for forming a non-volatile memory device comprising:
forming a preliminary device isolation layer configured to define an active region on a semiconductor substrate and define a gap region on the active region to have a higher upper surface than the active region;
forming a tunneling insulation layer on the active region;
forming a charge storage layer configured to cover the tunneling insulation layer, a side of the gap region, and an upper surface of the preliminary device isolation layer;
selectively removing a charge storage layer that covers the sides of the gap region and the upper surface of the preliminary device isolation layer;
forming a preliminary charge storage pattern configured to extend toward the active region;
recessing the preliminary device isolation layer;
forming a device isolation layer configured to include an upper surface under the preliminary charge storage pattern;
forming a blocking insulation layer and a gate conductive layer on the substrate; and
patterning the gate conductive layer, the blocking insulation layer, the preliminary charge storage pattern, and the tunneling insulation layer to form a gate electrode, a blocking insulation pattern, a charge storage pattern, and a tunneling insulation pattern.

2. The method of claim 1, wherein forming the preliminary device isolation layer comprises:
forming a mask pattern corresponding with the active region on the semiconductor substrate;
etching a part of the substrate using the mask pattern as an etching mask to form a trench;
filling the trench with insulation layer;
performing a planarization process to expose the upper surface of the mask; and
removing the mask pattern.

3. The method of claim 2, further comprising forming the gap region by removing the mask pattern.

4. The method of claim 3, wherein removing the mask pattern comprises etching a part of upper side walls of the preliminary device isolation layer, wherein the gap region has a larger width than the upper surface of the active region.

5. The method of claim 2, wherein the preliminary device isolation layer and the mask pattern comprise materials having etching selectivity.

6. The method of claim 1, wherein the preliminary device isolation layer and the charge storage layer comprise materials having etching selectivity.

7. The method of claim 1, wherein forming the preliminary charge storage pattern comprises:
filling the gap region with insulation layer on the charge storage layer;
performing a planarization process to expose an upper surface of the preliminary device isolation layer and form a gap insulation layer; and
removing the charge storage layer exposed between the gap insulation layer and the preliminary device isolation layer.

8. The method of claim 7, wherein the gap insulation layer and the charge storage layer comprise materials having etching selectivity.

9. The method of claim 7, wherein the gap insulation layer is etched to extend the preliminary charge storage pattern when the preliminary device isolation layer is recessed and wherein recessing the preliminary device isolation layer comprises etching the gap insulation layer to expose the preliminary charge storage pattern.

10. The method of claim 7, wherein the gap insulation layer and the preliminary device isolation layer comprise the same materials.

11. A non-volatile memory device comprising:
a device isolation layer disposed in a semiconductor substrate to define an active region;
a tunneling insulation pattern, a charge storage pattern, and a blocking insulation pattern disposed in the active region; and
a gate electrode disposed on the blocking insulation pattern,
wherein the charge storage pattern is cut on the device isolation layer and a lower surface of the charge storage pattern is higher than an upper surface of the device isolation layer.

12. The non-volatile memory device of claim 11, wherein the upper surface of the active region is higher than the upper surface of the device isolation layer.

13. The non-volatile memory device of claim 11, wherein the charge storage pattern covers the upper surface and sides of the tunneling insulation pattern.

14. The non-volatile memory device of claim 11, wherein the blocking insulation pattern and the gate electrode are interposed between substantially adjacent charge storage patterns of the gate electrode.

15. The non-volatile memory device of claim 11, wherein the charge storage pattern covers the upper surface and sides of the tunneling insulation pattern.

16. A method of forming a non-volatile memory device, comprising:
disposing a device isolation layer having an upper surface and configured to define an active region in a semiconductor substrate;
disposing a tunneling insulation pattern in the active region;
disposing a charge storage pattern having a lower surface that is higher than the upper surface of the device isolation layer, on the device isolation layer in the active region;
disposing a blocking insulation pattern in the active region; and
disposing a gate electrode on the blocking insulation pattern.

17. The method of claim 16, further comprising interposing the blocking insulation pattern and the gate electrode between substantially adjacent charge storage patterns.

18. The method of claim 16, wherein the upper surface of the active region is higher than the upper surface of the device isolation layer, wherein the charge storage pattern covers the upper surface and sides of the tunneling insulation pattern, and wherein the charge storage pattern covers the upper surface and sides of the tunneling insulation pattern.
